(19) United States
(12) Patent Application Publication
(10) Pub. No.: US 2016/0322342 A1
(43) Pub. Date: Nov. 3, 2016

(54) SEMICONDUCTOR DEVICE

(71) Applicant: Panasonic Intellectual Property Management Co., Ltd., Osaka (JP)

(72) Inventors: JUNICHI KIMURA, Osaka (JP); MASAHISA NAKAGUCHI, Osaka (JP); FUMITO ITOU, Osaka (JP); NORIMITSU HOZUMI, Osaka (JP)

(73) Assignee: Panasonic Intellectual Property Management Co. Lt, Osaka (JP)

(21) Appl. No.: 15/108,783

(22) PCT Filed: Jan. 7, 2015
(86) PCT No.: PCT/JP2015/000027

§ 371 Date: Jun. 29, 2016

(30) Foreign Application Priority Data
Jan. 15, 2014 (JP) 2014-004959

(51) Int. Cl. H01L 25/18; H01L 23/31; H01L 23/14; H01L 23/00; H01L 23/50; H01L 23/495

(52) U.S. Cl. CPC H01L 25/18; H01L 23/50; H01L 23/49575; H01L 23/49513; H01L 23/49558; H01L 23/49562; H01L 23/49551; H01L 23/49534; H01L 23/49572; H01L 23/142; H01L 24/32; H01L 23/3135; H01L 2224/32245

(57) ABSTRACT

A semiconductor device includes a substrate made of metal, a first metal wiring disposed above the substrate, a first semiconductor element and a second semiconductor element disposed above the first metal wiring, and a second metal wiring disposed above the first semiconductor element and the second semiconductor element. Furthermore, the semiconductor device includes a plurality of projections disposed in at least one of a space between each of the first semiconductor element and the second semiconductor element, and the first metal wiring, and a space between each of the first semiconductor element and the second semiconductor element, and the second metal wiring.

### TECHNICAL FIELD

The present invention relates to a semiconductor device provided with a semiconductor element.

### BACKGROUND ART

The semiconductor device is used as a device such as an industrial drive control device, home appliance drive control device provided with a motor, or car drive control device for an electric car or hybrid car. The semiconductor device is required to respond to an increase in power of a power device such as an industrial device, home appliance device, or car.

The semiconductor device is provided with the semiconductor element which is typified by a power element. The conventional semiconductor device is difficult to implement a long lifetime in some cases.

A case similar to the above background art is disclosed in Patent Literature 1.

### CITATION LIST

### Patent Literature

PTL 1: Unexamined Japanese Patent Publication No. 2013-243323

### SUMMARY OF THE INVENTION

A semiconductor device includes a substrate, a first metal wiring, a first semiconductor element, a second semiconductor element, a second metal wiring, and a plurality of projections. The substrate is made of metal. The first metal wiring is disposed above the substrate. The first semiconductor element and the second semiconductor element are disposed above the first metal wiring. The second metal wiring is continuously disposed above the first semiconductor element and the second semiconductor element. The second metal wiring electrically connects the first semiconductor element to the second semiconductor element. The plurality of projections are disposed in at least one of a space between each of the first semiconductor element and the second semiconductor element, and the first metal wiring, and a space between each of the first semiconductor element and the second semiconductor element, and the second metal wiring.

This semiconductor device can implement a long lifetime.

### BRIEF DESCRIPTION OF DRAWINGS

FIG. 1A is a cross-sectional view showing a semiconductor device in a first exemplary embodiment.

FIG. 1B is a cross-sectional view showing another semiconductor device in the first exemplary embodiment.

FIG. 2 is a cross-sectional view showing a semiconductor device in a second exemplary embodiment.

FIG. 3 is a cross-sectional view showing a semiconductor device in a third exemplary embodiment.

FIG. 4 is a cross-sectional view showing a semiconductor device in a fourth exemplary embodiment.

FIG. 5 is a cross-sectional view showing an essential part of a semiconductor device in a fifth exemplary embodiment.

FIG. 6 is a cross-sectional view showing an essential part of a semiconductor device in a sixth exemplary embodiment.

FIG. 7 is a cross-sectional view showing an essential part of a semiconductor device in a seventh exemplary embodiment.

FIG. 8 is a cross-sectional view showing an essential part of a semiconductor device in an eighth exemplary embodiment.

FIG. 9 is a cross-sectional view showing an essential part of a semiconductor device in a ninth exemplary embodiment.

### DESCRIPTION OF EMBODIMENTS

### First Exemplary Embodiment

1-1. Summary

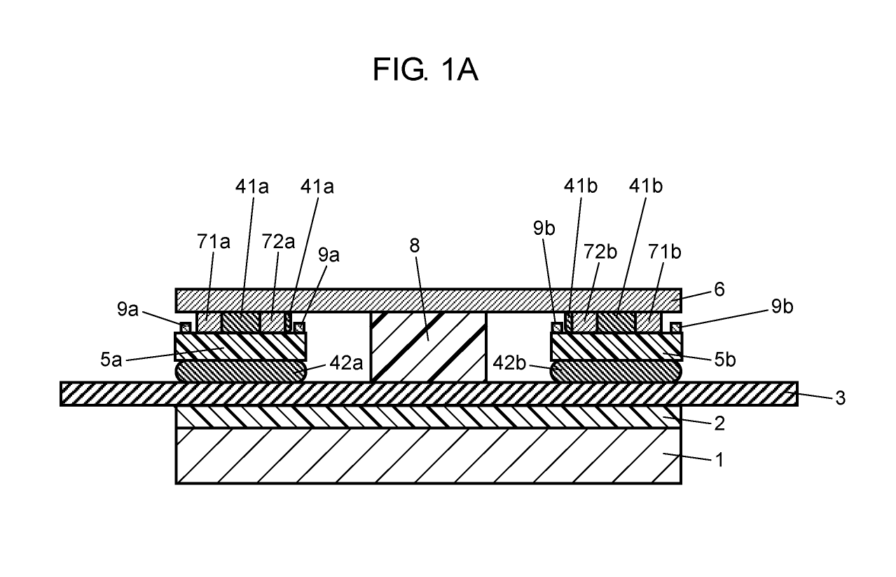

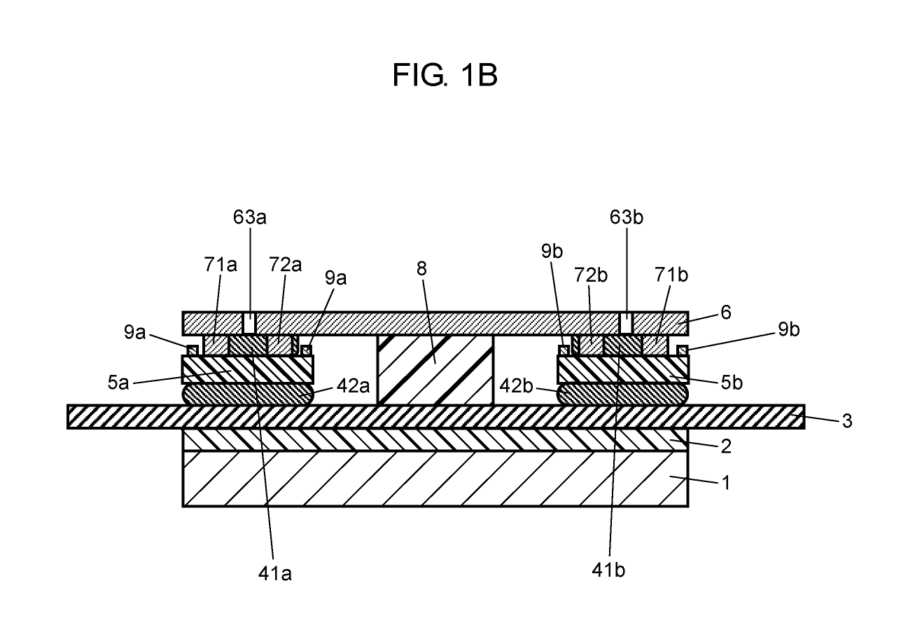

FIG. 1A is a cross-sectional view of a semiconductor device in the first exemplary embodiment. This semiconductor device is used in a power device requiring a high power.

The semiconductor device includes metal plate 1, lead frame 3, first semiconductor element 5a, second semiconductor element 5b, bus bar 6, and plurality of projections 71a, 72a, 71b, 72b.

First semiconductor element 5a and second semiconductor element 5b are disposed between lead frame 3 and bus bar 6.

Projections 71a, 72a are disposed between first semiconductor element 5a and bus bar 6. Projections 71b, 72b are disposed between second semiconductor element 5b and bus bar 6.

According to the first exemplary embodiment, a long distance between lead frame 3 and bus bar 6 can be provided with projections 71a, 72a, 71b, 72b.

Recently, due to an increase in power in the power device, a high voltage is applied between lead frame 3 and bus bar 6, and a large electric field is generated. According to a conventional semiconductor device, since projections 71a, 72a, 71b, 72b are not provided, first semiconductor element 5a and second semiconductor element 5b are affected by this electric field, which could deteriorate first semiconductor element 5a and second semiconductor element 5b. Therefore, a lifetime of the semiconductor device is reduced in some cases. However, according to the semiconductor device in the first exemplary embodiment, the long distance can be provided between lead frame 3 and bus bar 6. Thus, it is possible to reduce intensity of the electric field generated around first semiconductor element 5a and second semiconductor element 5b. As a result, first semiconductor element 5a and second semiconductor element 5b can be prevented from being deteriorated, so that the semiconductor device can implement a long lifetime.

1-2. Configuration

Hereinafter, the configuration of the semiconductor device in the first exemplary embodiment will be described in detail.

As shown in FIG. 1A, the semiconductor device in the first exemplary embodiment includes metal plate 1, bonding sheet 2, lead frame 3, solder bumps 42a, 42b, first semiconductor element 5a, second semiconductor element 5b, solder bumps 41a, 41b, projections 71a, 72a, 71b, 72b, bus bar 6, and spacer 8.

Hereinafter, each of the above components will be described.

Metal plate 1 corresponds to a substrate. Metal plate 1 externally releases heat generated during operations of first semiconductor element 5a and second semiconductor element 5b. That is, metal plate 1 serves as a radiator plate. A material of metal plate 1 is copper or aluminum, for example. The material of metal plate 1 may be a metal other than copper or aluminum as long as the material is a metal having relatively high rigidity.

Bonding sheet 2 is provided to stably bond and fix metal plate 1 and lead frame 3. Bonding sheet 2 is disposed between an upper surface of metal plate 1 and a lower surface of lead frame 3. Bonding sheet 2 has a laminated structure composed of a plurality of layers. According to the first exemplary embodiment, bonding sheet 2 has an insulating layer, and a bonding layer disposed further away from metal plate 1 than the insulating layer. That is, bonding sheet 2 has the insulating layer disposed on the upper surface of metal plate 1, and the bonding layer disposed on an upper surface of the insulating layer. A thickness of the insulating layer is about 190 μm to 210 μm. Furthermore, bonding sheet 2 may have a configuration in which an upper surface and a lower surface of an insulating layer is sandwiched between bonding layers, other than the above configuration. In this case, the insulating layer may be a plate made of aluminum, and the bonding layer may be a layer composed of solder.

Lead frame 3 corresponds to a first metal wiring. Lead frame 3 is a thin metal plate. Lead frame 3 is a wiring which connects lower surfaces of first semiconductor element 5a and second semiconductor element 5b to a ground electrode. Lead frame 3 is disposed above metal plate 1, and disposed on the upper surface of metal plate 1 with bonding sheet 2 interposed between them. A material of lead frame 3 is iron or nickel, for example.

Each of solder bump 42a and solder bump 42b corresponds to a conductive member. Solder bump 42a is disposed between lead frame 3 and first semiconductor element 5a. Solder bump 42b is disposed between lead frame 3 and second semiconductor element 5b. Each thickness of solder bumps 42a, 42b is 100 μm to 200 μm. Each material of solder bumps 42a, 42b is solder composed of alloy containing metal such as tin or silver. Solder bumps 42a, 42b do not contain lead. However, solder bumps 42a, 42b may contain lead in a case where their melting point is higher than a certain level, and lead frame 3 can be bonded to first semiconductor element 5a and second semiconductor element 5b with more than predetermined level of binding force. Furthermore, solder bumps 42a, 42b may contain particles each having a diameter of 70 μm to 90 μm. A material of the particles may be silver or resin.

First semiconductor element 5a is a power element. A source electrode, a drain electrode, and a gate electrode are formed on an upper surface of first semiconductor element 5a. First semiconductor element 5a is disposed on an upper surface of lead frame 3 with solder bump 42a interposed between them. Guard ring 9a is disposed along an outer circumference of the upper surface of first semiconductor element 5a. A shape of guard ring 9a is annular when guard ring 9a is viewed from a side above first semiconductor element 5a. Guard ring 9a is provided to reduce intensity of an electric field generated from first semiconductor element 5a. A material of guard ring 9a is metal.

Second semiconductor element 5b is a diode. Second semiconductor element 5b is disposed on the upper surface of lead frame 3 with solder bump 42b interposed between them. Guard ring 9b is disposed along an outer circumference of an upper surface of second semiconductor element 5b. A shape of guard ring 9b is annular when guard ring 9a is viewed from a side above second semiconductor element 5b. Guard ring 9b is provided to reduce intensity of an electric field generated from second semiconductor element 5b. A material of guard ring 9b is metal.

Each of solder bump 41a and solder bump 41b corresponds to a conductive member. Solder bump 41a is disposed between first semiconductor element 5a and bus bar 6. Solder bump 41b is disposed between second semiconductor element 5b and bus bar 6. A thickness of solder bumps 41a, 41b is 100 μm to 200 μm. A material of solder bumps 41a, 41b is similar to the material of solder bumps 42a, 42b.

Each of projection 71a, projection 72a, projection 71b, and projection 72b is integrally formed with bus bar 6, on a lower surface of bus bar 6. Projections 71a, 72a, 71b, 72b are bumps formed by dissolving a metal wire to be used in wire bonding. A material of projections 71a, 72a, 71b, 72b is gold.

Furthermore, projections 71a, 72a are disposed between first semiconductor element 5a and bus bar 6. A number of projections 71a, 72a disposed on the upper surface of first semiconductor element 5a is preferably two or more. Furthermore, A number of projections 71a, 72a is more preferably three or more. Thus, projections 71a, 72a are stably disposed on first semiconductor element 5a. Furthermore, projections 71a, 72a are preferably disposed in a position where projections 71a, 72a are in contact with corner portions of the upper surface of first semiconductor element 5a. In this case, projections 71a, 72a are stably disposed on first semiconductor element 5a. Furthermore, each surface of projections 71a, 72a which faces first semiconductor element 5a is a flat surface. Thus, the flat surfaces of projections 71a, 72a are directly in contact with first semiconductor element 5a. Thus, projections 71a, 72a are kept being physically connected to first semiconductor element 5a in a stable manner. Furthermore, projections 71a, 72a are kept being electrically connected to first semiconductor element 5a in a stable manner. In addition, tip ends of projections 71a, 72a are disposed in positions where tip ends of projections 71a, 72a do not stride across a plurality of adjacent electrodes of first semiconductor element 5a. Thus, an electric short circuit can be prevented from being caused between the plurality of electrodes. Furthermore, according to the first exemplary embodiment, a volume of solder bump 41a which is disposed along a circumference of projection 71a is smaller than a volume of solder bump 41a which is disposed along a circumference of projection 72a positioned inside projection 71a. In addition, solder bump 41a is provided so as not to reach an outer circumstance of projection 71a as much as possible. Therefore, solder bump 41a can be prevented from being affected by the electric field. As a result, migration can be prevented from occurring in first semiconductor element 5a, and the semiconductor device can be prevented from deteriorating with age. Furthermore, an electric short circuit with another adjacently disposed semiconductor device can be prevented from being caused.

Furthermore, projections 71b, 72b are disposed between second semiconductor element 5b and bus bar 6. A number of projections 71b, 72b disposed on the upper surface of second semiconductor element 5b is preferably two or more. Furthermore, A number of projections 71a, 72a is more preferably three or more. Thus, projections 71b, 72b are stably disposed on second semiconductor element 5b. Furthermore, projections 71b, 72b are preferably disposed in a position where projections 71a, 72a are in contact with corner portions of the upper surface of second semiconductor element 5b. Thus, projections 71b, 72b are stably disposed on second semiconductor element 5b. Furthermore, each surface of projections 71b, 72b which faces second semiconductor element 5b is a flat surface. Thus, the flat surfaces of projections 71b, 72b are directly in contact with second semiconductor element 5b. Thus, projections 71b, 72b are kept being physically and electrically connected to second semiconductor element 5b in a stable manner. In addition, tip ends of projections 71b, 72b are disposed in positions where tip ends of projections 71a, 72a do not stride across a plurality of adjacent electrodes of second semiconductor element 5b. Thus, an electric short circuit can be prevented from being caused between the plurality of electrodes. Furthermore, according to the first exemplary embodiment, a volume of solder bump 41b which is disposed along a circumference of projection 71b is smaller than a volume of solder bump 41b which is disposed along a circumference of projection 72b positioned inside projection 71b. In addition, solder bump 41b is provided so as not to reach an outer circumstance of projection 71b as much as possible. Thus, solder bump 41b can be prevented from being affected by the electric field. As a result, migration can be prevented from occurring in second semiconductor element 5b, and the semiconductor device can be prevented from deteriorating with age. Furthermore, an electric short circuit with another adjacently disposed semiconductor device can be prevented from being caused.

Bus bar 6 corresponds to a second metal wiring. Bus bar 6 is a metal plate. Bus bar 6 is disposed above first semiconductor element 5a, and disposed on the upper surface of first semiconductor element 5a with solder bump 41a interposed between them. Furthermore, bus bar 6 is disposed above second semiconductor element 5b, and disposed on the upper surface of second semiconductor element 5b with solder bump 41b interposed between them. Thus, bus bar 6 is continuously disposed so as to stride over first semiconductor element 5a and second semiconductor element 5b. Bus bar 6 electrically connects first semiconductor element 5a to second semiconductor element 5b.

Spacer 8 is sandwiched between lead frame 3 and bus bar 6. Due to spacer 8, a distance between lead frame 3 and bus bar 6 can be maintained at a constant length.

1-3. Manufacturing Method

Hereinafter, the method for manufacturing the semiconductor device in the first exemplary embodiment will be described.

First, metal plate 1 is prepared.

Next, bonding sheet 2 is bonded onto metal plate 1.

Next, lead frame 3 is disposed on bonding sheet 2, and lead frame 3 is bonded to bonding sheet 2.

Next, solder bumps 42a, 42b are formed on lead frame 3. Then, spacer 8 is disposed in a center portion of lead frame 3. Then, first semiconductor element 5a is disposed on solder bump 42a. Furthermore, second semiconductor element 5b is disposed on solder bump 42b.

Next, solder bump 41a is formed on first semiconductor element 5a. Furthermore, solder bump 41b is formed on second semiconductor element 5b.

Next, projections 71a, 72a, 71b, 72b are formed at predetermined positions of bus bar 6. An integrated flat metal plate is pressed against the tip ends of projections 71a, 72a, 71b, 72b to level out all projections 71a, 72a, 71b, 72b.

Next, bus bar 6 is disposed so that projections 71a, 72a face first semiconductor element 5a and projections 71b, 72b face second semiconductor element 5b.

Next, solder bumps 41a, 41b, and solder bumps 42a, 42b are cured in a reflow process.

Through the above processes, the semiconductor device in the first exemplary embodiment is manufactured.

1-4. Effect

Hereinafter, the effect of the semiconductor device in the first exemplary embodiment will be described.

According to the first exemplary embodiment, the long lifetime can be implemented in the semiconductor device. Hereinafter, reasons for that will be described. According to the first exemplary embodiment, since projections 71a, 72a are provided, the distance between first semiconductor element 5a and bus bar 6 can be maintained at the constant length. In addition, since projections 71b, 72b are provided, the distance between second semiconductor element 5b and bus bar 6 can be maintained at the constant length. Accordingly, the distance between lead frame 3 and bus bar 6 can also be maintained at constant length. Therefore, even when a high voltage is applied between lead frame 3 and bus bar 6, intensity of the electric field generated between lead frame 3 and bus bar 6 can be reduced. As a result, first semiconductor element 5a and second semiconductor element 5b can be prevented from deteriorating, and the long lifetime can be implemented in the semiconductor device. In addition, an automobile-related device is used in severely changing environments. Thus, such device is required to improve safety and durability and prolong its lifetime even under that condition. The semiconductor device in the first exemplary embodiment has enhanced safety and durability and a long lifetime. Therefore, this semiconductor device can be very useful as a semiconductor device to be used in the automobile-related device.

Furthermore, according to the semiconductor device in the first exemplary embodiment, plurality of projections 71a, 72a are disposed on first semiconductor element 5a, and plurality of projections 71b, 72b are disposed on second semiconductor element 5b. Therefore, bus bar 6 can be prevented from tilting. Thus, the distance between first semiconductor element 5a and bus bar 6 and the distance between second semiconductor element 5b and bus bar 6 can be each maintained at the predetermined length with high precision. Furthermore, the distance between bus bar 6 and lead frame 3 can also be maintained at the predetermined length with high precision.

Furthermore, according to the first exemplary embodiment, each of projections 71a, 72a, 71b, 72b has the flat surface which faces one of first semiconductor element 5a and second semiconductor element 5b. Thus, the electric connection and the physical connection can be improved between first semiconductor element 5a and second semiconductor element 5b, and bus bar 6. Furthermore, at least one of projections 71a, 72a, 71b, 72b may have the flat surface which faces one of first semiconductor element 5a and second semiconductor element 5b.

1-5. Variation

FIG. 1B is a cross-sectional view of another semiconductor device in the first exemplary embodiment.

As shown in FIG. 1B, bus bar 6 has through holes 63a, 63b. Each of through holes 63a, 63b penetrates between an upper surface and a lower surface of bus bar 6.

Through hole 63a is provided in a region of bus bar 6 so as to face first semiconductor element 5a. That is, through hole 63a is provided in the region of bus bar 6 so as to face solder bump 41a.

Through hole 63b is provided in a region of bus bar 6 so as to face second semiconductor element 5b. That is, through hole 63b is provided in the region of bus bar 6 so as to face solder bump 41b.

Thus, by providing through hole 63a, even when air bubbles are generated in solder bump 41a in the process for manufacturing the semiconductor device, the air bubbles can be discharged via through hole 63a. Similarly, by providing through hole 63b, even when air bubbles are generated in solder bump 41b in the process for manufacturing the semiconductor device, the air bubbles can be discharged via through hole 63b. As a result, binding force can be enhanced between first semiconductor element 5a and second semiconductor element 5b, and bus bar 6. In addition, the binding force can be maintained for a long period of time.

Furthermore, the through hole may be formed at least one of the regions of bus bar 6 so as to face first semiconductor element 5a or second semiconductor element 5b. In this case, air bubbles can be reduced in the solder bump which faces the through hole.

Furthermore, according to the first exemplary embodiment, although spacer 8 is provided between lead frame 3 and bus bar 6, spacer 8 is not an indispensable component. Even when spacer 8 is not provided, bus bar 6 can be prevented from tilting by providing projections 71a, 72a, 71b, 72b. Furthermore, by providing projections 71a, 72a, 71b, 72b, the distance between lead frame 3 and bus bar 6 can be stably maintained at the predetermined length.

Furthermore, according to the first exemplary embodiment, although solder bumps 41a, 41b, 42a, 42b are used as the conductive members, members other than solder bumps 41a, 41b, 42a, 42b may be used. For example, the conductive member may be formed using a conductive bonding agent composed of resin containing gold, silver paste, or metal fine particles.

In addition, according to the first exemplary embodiment, although first semiconductor element 5a is the power element, and second semiconductor element 5b is the diode, first semiconductor element 5a and second semiconductor element 5b may be other semiconductor elements.

### Second Exemplary Embodiment

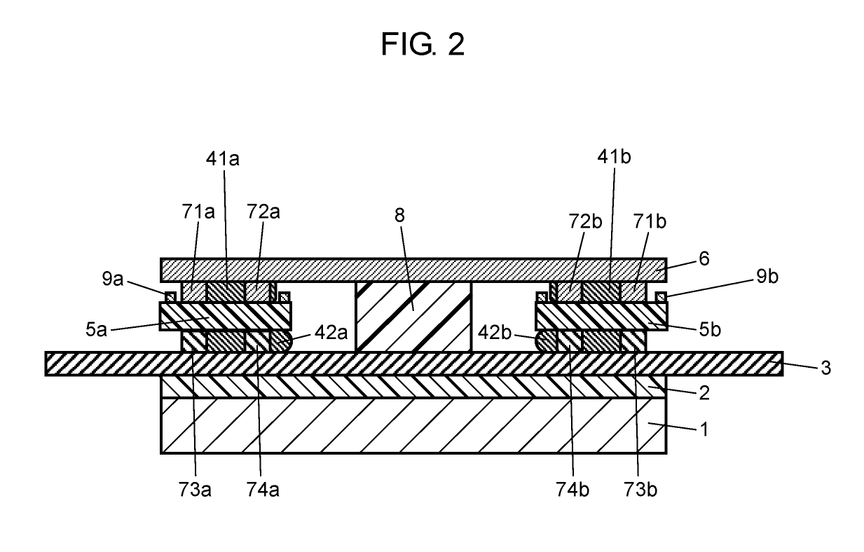

FIG. 2 is a view showing a cross-sectional surface of a semiconductor device in the second exemplary embodiment. Furthermore, a description for a configuration common to the first exemplary embodiment is omitted.

As shown in FIG. 2, the semiconductor device in the second exemplary embodiment includes projection 73a and projection 74a between first semiconductor element 5a and lead frame 3. Furthermore, the semiconductor device includes projection 73b and projection 74b between second semiconductor element 5b and lead frame 3.

Each of projection 73a, 74a, 73b, 74b is integrally formed with lead frame 3, on an upper surface of lead frame 3. Each of projections 73a, 74a, 73b, 74b serves as a bump formed by dissolving metal. A number of projections 73a, 74a disposed on a lower surface of first semiconductor element 5a is preferably two or more. Furthermore, a number of projections 73a, 74a is more preferably three or more. Thus, first semiconductor element 5a is stably disposed on projections 73a, 74a. Furthermore, tip ends of projections 73a, 74a are preferably in contact with corner portions of the lower surface of first semiconductor element 5a. Thus, first semiconductor element 5a is stably disposed on projections 73a, 74a. Furthermore, each surface of projections 73a, 74a which faces first semiconductor element 5a is a flat surface. Thus, the flat surfaces of projections 73a, 74a are directly in contact with first semiconductor element 5a. In this case, projections 73a, 74a are kept being physically and electrically connected to first semiconductor element 5a in a stable manner. In addition, according to the second exemplary embodiment, a volume of solder bump 42a which is disposed along a circumference of projection 73a is smaller than a volume of solder bump 42a which is disposed along a circumference of projection 74a positioned inside projection 73a. In addition, solder bump 42a is provided so as not to reach an outer circumstance of projection 73a as much as possible. Thus, solder bump 42a can be prevented from being affected by an electric field. As a result, migration can be prevented from occurring in first semiconductor element 5a, and the semiconductor device can be prevented from deteriorating with age. Furthermore, an electric short circuit with another adjacently disposed semiconductor device can be prevented from being caused.

Furthermore, a number of projections 73b, 74b disposed on a lower surface of second semiconductor element 5b is preferably two or more. Furthermore, a number of projections 73b, 74b is more preferably three or more. Thus, second semiconductor element 5b is stably disposed on projections 73b, 74b. Furthermore, tip ends of projections 73b, 74b are preferably in contact with corner portions of the lower surface of second semiconductor element 5b. Thus, second semiconductor element 5b is stably disposed on projections 73b, 74b. Furthermore, each surface of projections 73b, 74b which faces second semiconductor element 5b is a flat surface. Thus, the flat surfaces of projections 73b, 74b are directly in contact with second semiconductor element 5b. In this case, projections 73b, 74b are kept being physically and electrically connected to second semiconductor element 5b in a stable manner. In addition, according to the second exemplary embodiment, a volume of solder bump 42b disposed along a circumference of projection 73b is smaller than a volume of solder bump 42b disposed along a circumference of projection 74b positioned inside projection 73b. In addition, solder bump 42b is provided so as not to reach an outer circumstance of projection 73b as much as possible. Thus, solder bump 42b can be prevented from being affected by an electric field. As a result, migration can be prevented from occurring in second semiconductor element 5b, and the semiconductor device can be prevented from deteriorating with age. Furthermore, an electric short circuit with another adjacently disposed semiconductor device can be prevented from being caused.

Furthermore, projections 73a, 74a, 73b, 74b may be formed in a process before lead frame 3 is disposed or after lead frame 3 is disposed on bonding sheet 2, in the manufacturing method shown in the first exemplary embodiment.

According to the second exemplary embodiment, due to projections 71a, 72a, 71b, 72b, a distance between each of first semiconductor element 5a and second semiconductor element 5b, and bus bar 6 can be maintained at a predetermined length. Furthermore, due to projections 73a, 74a, 73b, 74b, a distance between each of first semiconductor element 5a and second semiconductor element 5b, and lead frame 3 can be maintained at a predetermined length. Therefore, a distance between lead frame 3 and bus bar 6 can be maintained at a predetermined length. As a result, first semiconductor element 5a and second semiconductor element 5b can be prevented from being affected by an electric field, so that a long lifetime can be implemented in the semiconductor device.

Furthermore, according to the second exemplary embodiment, each of projections 73a, 74a, 73b, 74b has a flat surface which faces one of first semiconductor element 5a and second semiconductor element 5b. Thus, the electric connection and the physical connection can be improved between each of first semiconductor element 5a and second semiconductor element 5b, and lead frame 3. Furthermore, at least one surface of projections 73a, 74a, 73b, 74b may have a flat surface.

### Third Exemplary Embodiment

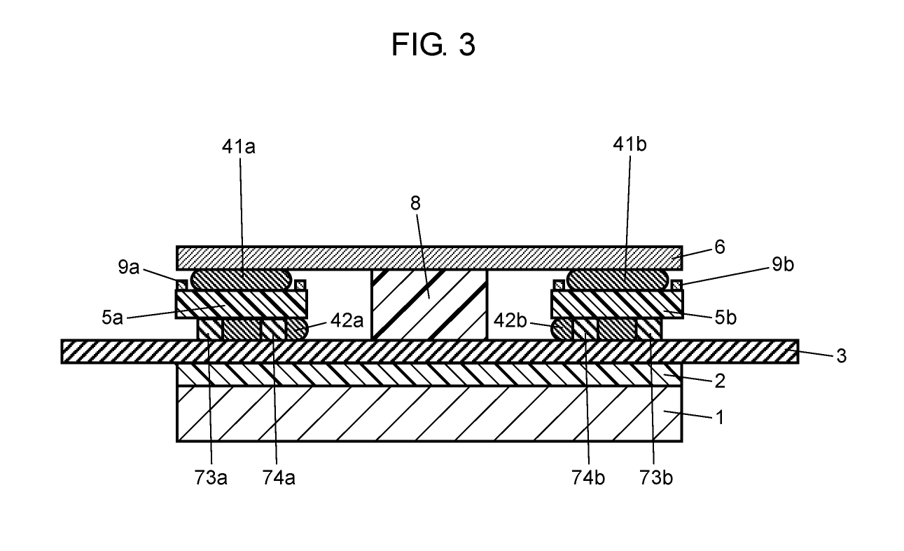

FIG. 3 is a view showing a cross-sectional surface of a semiconductor device in the third exemplary embodiment. In addition, a description for a configuration common to the first exemplary embodiment or the second exemplary embodiment is omitted.

As shown in FIG. 3, the semiconductor device in the third exemplary embodiment is configured such that projections 73a, 74a are disposed between first semiconductor element 5a and lead frame 3, and projections 73b, 74b are disposed between second semiconductor element 5b and lead frame 3. A projection is not disposed between first semiconductor element 5a and bus bar 6, and between second semiconductor element 5b and bus bar 6. First semiconductor element 5a and bus bar 6 are connected with solder bump 41a, and second semiconductor element 5b and bus bar 6 are connected with solder bump 41b.

According to the third exemplary embodiment, due to projections 73a, 74a, 73b, 74b, a distance between each of first semiconductor element 5a and second semiconductor element 5b, and lead frame 3 can be maintained at a predetermined length. Therefore, a distance between lead frame 3 and bus bar 6 can be maintained at a predetermined length or more. As a result, first semiconductor element 5a and second semiconductor element 5b can be prevented from being affected by an electric field, so that a long lifetime can be implemented in the semiconductor device.

### Fourth Exemplary Embodiment

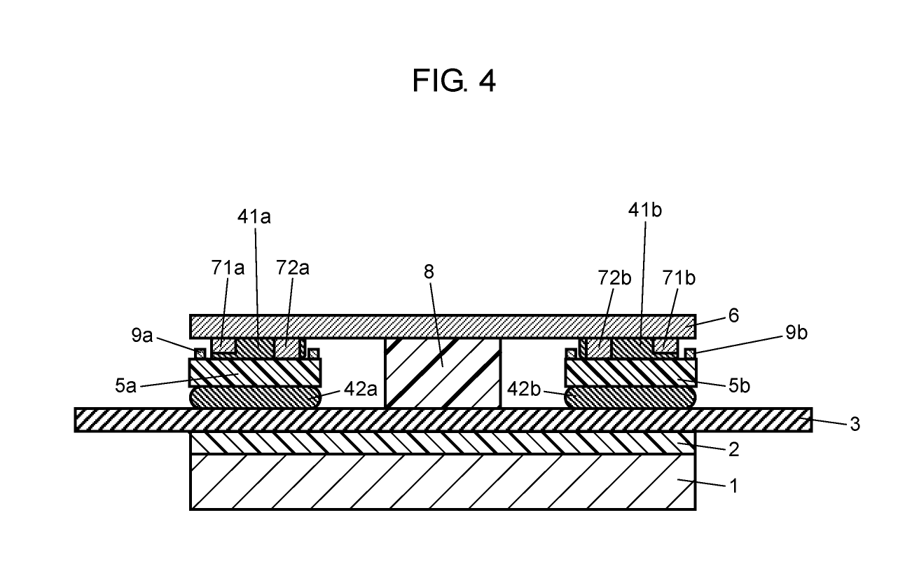

FIG. 4 is a view showing a cross-sectional surface of a semiconductor device in the fourth exemplary embodiment. In addition, a description for a configuration common to the first exemplary embodiment is omitted.

As shown in FIG. 4, the semiconductor device in the fourth exemplary embodiment is configured such that projection 72a of projections 71a, 72a provided on first semiconductor element 5a is directly in contact with first semiconductor element 5a. Meanwhile, projection 71a is not directly in contact with first semiconductor element 5a, and separated from first semiconductor element 5a. In addition, projection 72b of projections 71b, 72b provided on second semiconductor element 5b is directly in contact with second semiconductor element 5b. Meanwhile, projection 71b is not directly in contact with second semiconductor element 5b, and separated from second semiconductor element 5b.

According to the fourth exemplary embodiment, since projection 72a is directly in contact with first semiconductor element 5a, electric conductivity can be enhanced between first semiconductor element 5a and bus bar 6. Furthermore, since projection 72b is directly in contact with second semiconductor element 5b, electric conductivity can be enhanced between second semiconductor element 5b and bus bar 6.

In addition, projection 71a is separated from first semiconductor element 5a. Thus, solder bump 41a flows in between first semiconductor element 5a and projection 71a. In this case, when substrate 1 is horizontally set, parallelism can be enhanced between substrate 1 and bus bar 6. Furthermore, projection 7 lb is separated from second semiconductor element 5b. Thus, solder bump 42a flows in between second semiconductor element 5b and projection 71b, and parallelism can be enhanced between substrate 1 and bus bar 6.

That is, at least one of projections 71a, 72a, 71b, 72b is to be directly in contact with one of first semiconductor element 5a and second semiconductor element 5b, so that electric conductivity can be improved.

Meanwhile, at least one of projections 71a, 72a, 71b, 72b is to be separated from each of first semiconductor element 5a and second semiconductor element 5b, so that the parallelism can be enhanced between bus bar 6 and substrate 1.

### Fifth Exemplary Embodiment

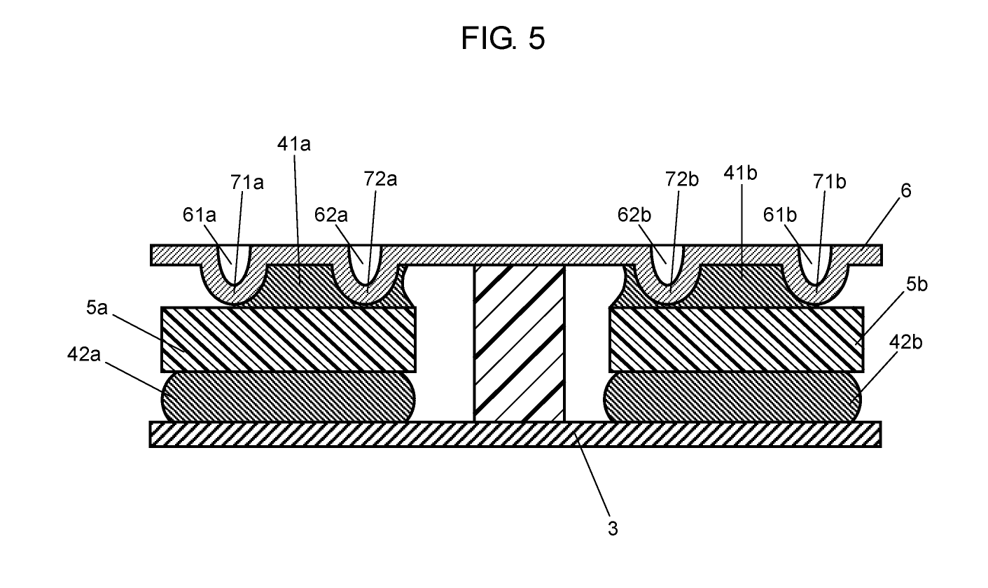

FIG. 5 is a cross-sectional view showing an essential part of a semiconductor device in the fifth exemplary embodiment. In the fifth exemplary embodiment, a description for a configuration common to the first exemplary embodiment is omitted. There is a main difference between the fifth exemplary embodiment and the first exemplary embodiment in a configuration of projections 71a, 72a, 71b, 72b and a manufacturing method.

Projections 71a, 72a, 71b, 72b are formed by punching bus bar 6. That is, according to the fifth exemplary embodiment, projections 71a, 72a, 71b, 72b are formed by pressing an upper surface of bus bar 6 downward with a die. Thus, plurality of recessed portions 61a, 62a, 61b, 62b are formed in the upper surface of bus bar 6. Plurality of recessed portions 61a, 62a, 61b, 62b are paired with plurality of projections 71a, 72a, 71b, 72b, respectively. Each of recessed portions 61a, 62a, 61b, 62b has a semi-oval spherical shape. In addition, each of recessed portions 61a, 62a, 61b, 62b may have a cuboidal shape or linear shape other than the semi-oval spherical shape.

According to the fifth exemplary embodiment, since recessed portions 61a, 62a, 61b, 62b are formed in the upper surface of bus bar 6, flexibility of bus bar 6 is improved. Therefore, when solder bumps 41a, 41b are thermally expanded in a reflow process for solder bumps 41a, 41b, bus bar 6 is elastically deformed. As a result, a stress load toward first semiconductor element 5a and second semiconductor element 5b can be reduced. Thus, electric resistance can be uniformly provided between bus bar 6, and each of first semiconductor element 5a and second semiconductor element 5b, so that a potential can be stabilized.

Furthermore, according to the fifth exemplary embodiment, when the semiconductor device is covered with a molding resin, the molding resin enters inner sides of recessed portions 61a, 62a, 61b, 62b. Therefore, adhesiveness is improved between the molding resin and the upper surface of bus bar 6. Thus, a gap is hardly generated between the molding resin and bus bar 6, so that it is possible to solve the problem that water from the molding resin is pooled in the gap.

### Sixth Exemplary Embodiment

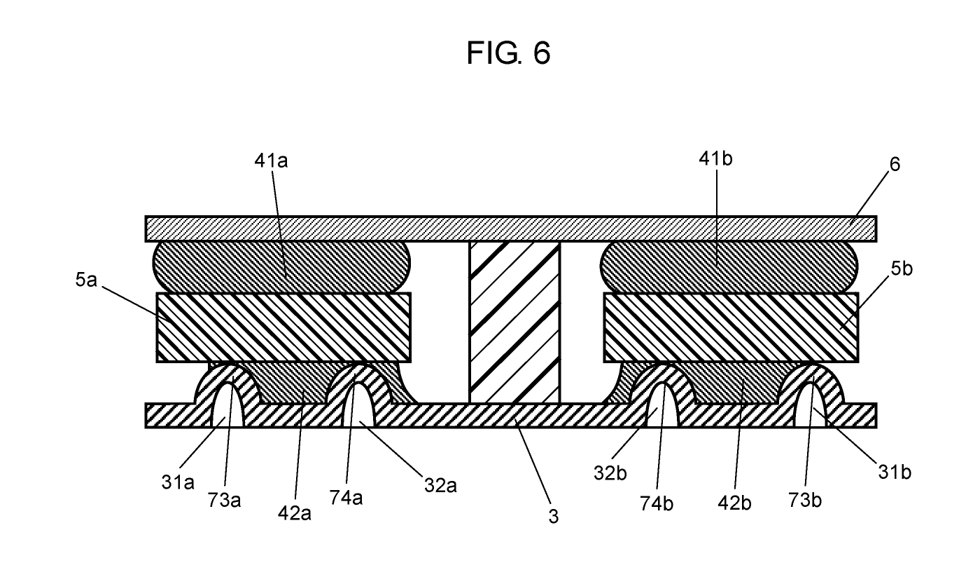

FIG. 6 is a cross-sectional view showing an essential part of a semiconductor device in the sixth exemplary embodiment. In the sixth exemplary embodiment, similar to the third exemplary embodiment, projections 73a, 74a, 73b, 74b are disposed between lead frame 3, and each of first semiconductor element 5a and second semiconductor element 5b. In the sixth exemplary embodiment, a description for a configuration common to the third exemplary embodiment is omitted.

There is a main difference between the sixth exemplary embodiment and the third exemplary embodiment in a configuration of projections 73a, 74a, 73b, 74b and a manufacturing method.

Projections 73a, 74a, 73b, 74b shown in FIG. 6 are formed by punching lead frame 3. That is, according to the sixth exemplary embodiment, projections 73a, 74a, 73b, 74b are formed by pressing a lower surface of lead frame 3 upward with a die. Thus, plurality of recessed portions 31a, 32a, 31b, 32b are formed in the lower surface of lead frame 3. Plurality of recessed portions 31a, 32a, 31b, 32b are paired with plurality of projections 73a, 74a, 73b, 74b, respectively. Each of recessed portions 31a, 32a, 31b, 32b has a semi-oval spherical shape. In addition, each of recessed portions 31a, 32a, 31b, 32b may have a cuboidal shape or linear shape other than the semi-oval spherical shape.

According to the sixth exemplary embodiment, since recessed portions 31a, 32a, 31b, 32b are formed in the lower surface of lead frame 3, flexibility of lead frame 3 is improved. Therefore, even when solder bumps 42a, 42b are thermally expanded in a reflow process for solder bumps 42a, 42b, lead frame 3 is elastically deformed. As a result, a stress load toward first semiconductor element 5a and second semiconductor element 5b can be reduced. Thus, electric resistance can be uniformly provided between lead frame 3, and each of first semiconductor element 5a and second semiconductor element 5b, so that a potential can be stabilized.

### Seventh Exemplary Embodiment

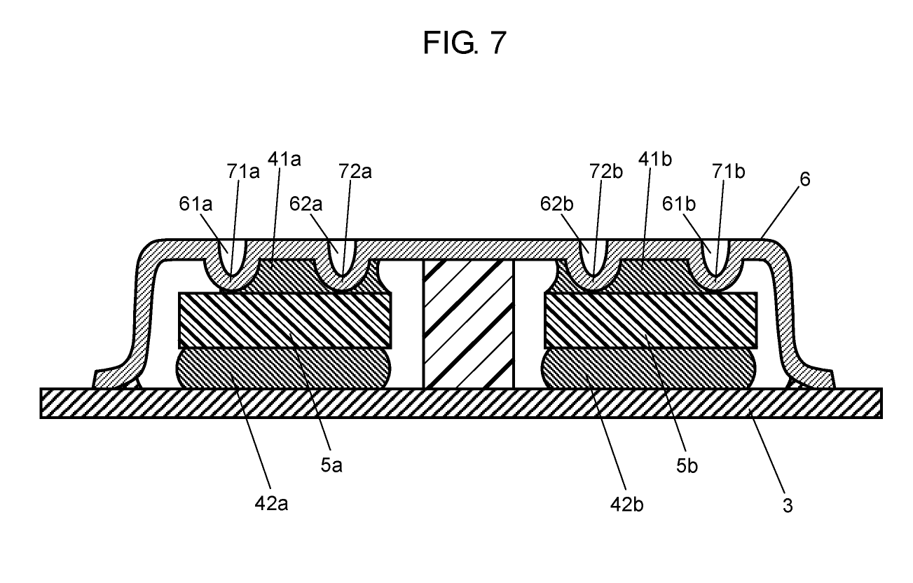

FIG. 7 is a cross-sectional view showing an essential part of a semiconductor device in the seventh exemplary embodiment. In the seventh exemplary embodiment, similar to the fifth exemplary embodiment, projections 71a, 72a, 71b, 72b are formed by a punching process. In addition, recessed portions 61a, 62a, 61b, 62b are formed in an upper surface of bus bar 6. In the seventh exemplary embodiment, a description for a configuration common to the fifth exemplary embodiment is omitted.

There is a main difference between the seventh exemplary embodiment and the fifth exemplary embodiment in a configuration of bus bar 6. Bus bar 6 is bent and connected to lead frame 3. Bus bar 6 and lead frame 3 are bonded with solder.

According to the seventh exemplary embodiment, since bus bar 6 is bent, flexibility of bus bar 6 is enhanced. Therefore, when solder bumps 41a, 41b are thermally expanded in a reflow process for solder bumps 41a, 41b, bus bar 6 is elastically deformed. As a result, a stress load toward first semiconductor element 5a and second semiconductor element 5b can be reduced. Thus, electric resistance can be uniformly provided between bus bar 6, and each of first semiconductor element 5a and second semiconductor element 5b, so that a potential can be stabilized.

Furthermore, according to the seventh exemplary embodiment, a source electrode formed on an upper surface of first semiconductor element 5a is connected to lead frame 3 through bus bar 6. That is, the source electrode is connected to the ground through lead frame 3. Therefore, a potential is prevented from being generated between the source electrode and a lower surface of first semiconductor element 5a, and a current collapse can be prevented.

### Eighth Exemplary Embodiment

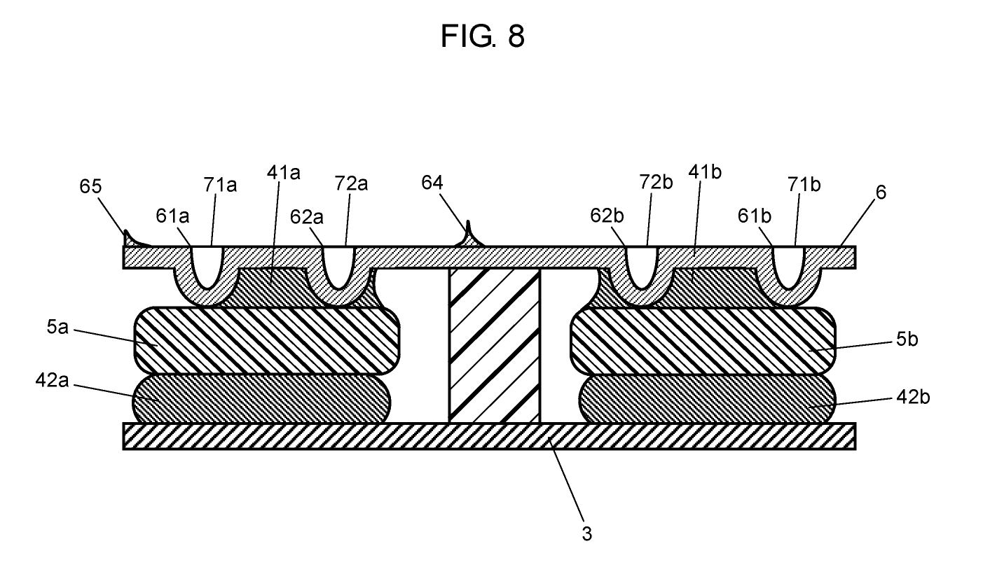

FIG. 8 is a cross-sectional view showing an essential part of a semiconductor device in the eighth exemplary embodiment. In the eighth exemplary embodiment, similar to the fifth exemplary embodiment, projections 71a, 72a, 71b, 72b are formed by a punching process. In addition, recessed portions 61a, 62a, 61b, 62b are formed in an upper surface of bus bar 6. In the eighth exemplary embodiment, a description for a configuration common to the fifth exemplary embodiment is omitted.

There is a main difference between the eighth exemplary embodiment and the fifth exemplary embodiment in a configuration of bus bar 6 and a configuration of first semiconductor element 5a and second semiconductor element 5b.

Protruded portion 64 and protruded portion 65 are formed on an upper surface of bus bar 6. Each volume of protruded portions 64, 65 is smaller than each volume of projections 71a, 72a, 71b, 72b. Each tip end of protruded portions 64, 65 is smaller and sharper than each tip end of projections 71a, 72a, 71b, 72b. Here, bus bar 6 is formed by punching a metal plate from its lower surface to upper surface shown in FIG. 8. Thus, protruded portions 64, 65 which are called a burr are formed on the upper surface of bus bar 6. In the eighth exemplary embodiment, projections 71a, 72a, 71b, 72b are formed on a surface opposite to the surface having protruded portions 64, 65.

According to the eighth exemplary embodiment, since protruded portions 64, 65 each having the sharp tip end are disposed on the upper surface of bus bar 6, compared to a case where protruded portions 64, 65 are disposed on a lower surface, an electric field can be prevented from concentrating on protruded portions 64, 65.

Furthermore, when the semiconductor device is covered with a molding resin, adhesiveness can be improved between the molding resin and the upper surface of bus bar 6 due to protruded portions 64, 65.

Still furthermore, according to the eighth exemplary embodiment, first semiconductor element 5a and second semiconductor element 5b each has a rounded corner portion. Thus, according to the eighth exemplary embodiment, an electric field can be prevented from concentrating on first semiconductor element 5a and second semiconductor element 5b.

### Ninth Exemplary Embodiment

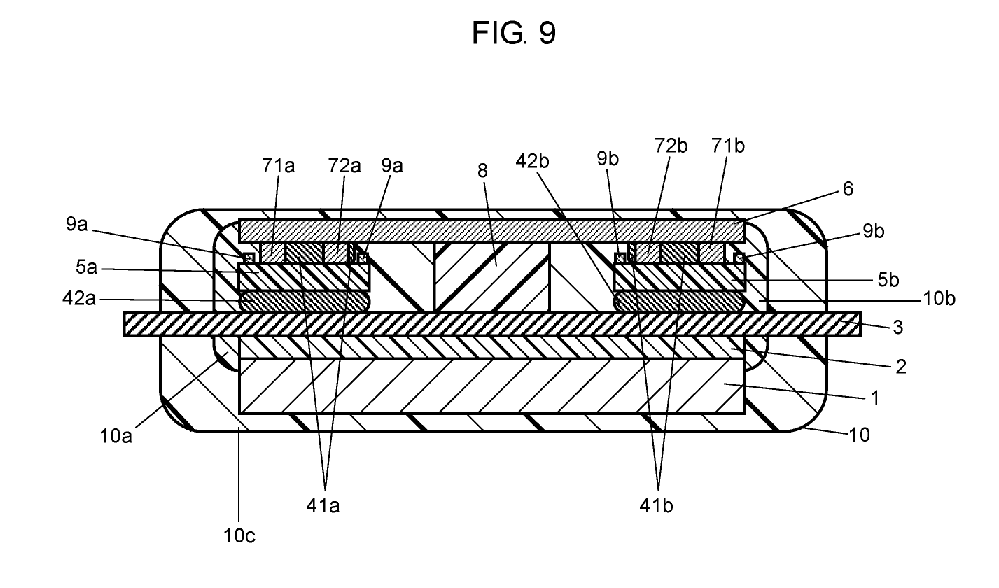

FIG. 9 is a cross-sectional view showing a semiconductor device in the ninth exemplary embodiment. In the ninth exemplary embodiment, a description for a configuration common to the first exemplary embodiment is omitted.

According to the ninth exemplary embodiment, the semiconductor device in the first exemplary embodiment shown in FIG. 1A is covered with a molding resin. That is, the semiconductor device shown in FIG. 9 includes molding resin portion 10 which integrally covers metal plate 1, lead frame 3, first semiconductor element 5a, second semiconductor element 5b, plurality of projections 71a, 72a, 71b, 72b, and bus bar 6.

Molding resin portion 10 has first region 10a, second region 10b, and third region 10c. A material of first region 10a is the same as a material of third region 10c. Therefore, a dielectric constant of first region 10a is the same as a dielectric constant of third region 10c. Meanwhile, a material of second region 10b is different from the material of first region 10a and third region 10c. Therefore, a dielectric constant of second region 10b is different from the dielectric constant of first region 10a and third region 10c. For example, in a case where an intense electric field is generated in first region 10a and third region 10c, the dielectric constant of first region 10a and third region 10c is set lower than the dielectric constant of second region 10b, concentration of the electric field can be alleviated.

Furthermore, in the first to ninth exemplary embodiments, the terms regarding the directions such as “upper surface”, “lower surface”, “upward”, and “downward” are provided based on the direction of the drawing for the sake of convenience. Therefore, these terms can be changed depending on an arrangement direction of the semiconductor device or a viewing direction.

### INDUSTRIAL APPLICABILITY

The semiconductor device according to the exemplary embodiments can prevent the semiconductor element from being deteriorated. Accordingly, the semiconductor device is useful as a control device for a mobile unit, such as a car, for which high reliability is required, and home appliance drive control device.

### REFERENCE MARKS IN THE DRAWINGS

1 metal plate (substrate)

2 bonding sheet

3 lead frame (first metal wiring)

31a, 32a, 31b, 32b recessed portion

41a, 42a solder bump (conductive member)

41b, 42b solder bump (conductive member)

5a first semiconductor element

5b second semiconductor element

6 bus bar (second metal wiring)

61a, 62a, 61b, 62b recessed portion

63a, 63b through hole

64, 65 protruded portion

71a, 72a, 73a, 74a, 71b, 72b, 73b, 74b projection

8 spacer

9a, 9b guard ring

10 molding resin portion

10a first region

10b second region

10c third region

1. A semiconductor device comprising:
a substrate made of metal;
a first metal wiring disposed above the substrate;
a first semiconductor element and a second semiconductor element disposed above the first metal wiring;
a second metal wiring continuously disposed above the first semiconductor element and above the second semiconductor element to electrically connect the first semiconductor element to the second semiconductor element; and
a plurality of projections disposed in at least one of a space between each of the first semiconductor element and the second semiconductor element, and the first metal wiring, and a space between each of the first semiconductor element and the second semiconductor element, and the second metal wiring.

2. The semiconductor device according to claim 1, further comprising a plurality of conductive members disposed between the first metal wiring and the first semiconductor element, and between the first metal wiring and the second semiconductor element.

3. The semiconductor device according to claim 1, further comprising a plurality of conductive members disposed between the second metal wiring and the first semiconductor element, and between the second metal wiring and the second semiconductor element.

4. The semiconductor device according to claim 2, wherein
a material of the plurality of conductive members is solder.

5. The semiconductor device according to claim 1, further comprising a bonding sheet disposed between the substrate and the first metal wiring.

6. The semiconductor device according to claim 5, wherein the bonding sheet has an insulating layer, and a bonding layer disposed on an upper surface of the insulating layer.

7. The semiconductor device according to claim 1, wherein
the first semiconductor element is a power element, and
the second semiconductor element is a diode.

8. The semiconductor device according to claim 1, wherein
a through hole is formed in the second metal wiring to be disposed in at least one of a region facing the first semiconductor element and a region facing the second semiconductor element.

9. The semiconductor device according to claim 1, wherein
the plurality of projections include two or more projections disposed between the first semiconductor element and the first metal wiring, and two or more projections disposed between the second semiconductor element and the first metal wiring.

10. The semiconductor device according to claim 1, wherein
the plurality of projections include two or more projections disposed between the first semiconductor element and the second metal wiring, and two or more projections disposed between the second semiconductor element and the second metal wiring.

11. The semiconductor device according to claim 1, wherein at least one of the plurality of projections has a flat surface facing one of the first semiconductor element and the second semiconductor element.

12. The semiconductor device according to claim 1, wherein
at least one of the plurality of projections is directly in contact with one of the first semiconductor element and the second semiconductor element.

13. The semiconductor device according to claim 1, wherein
at least one of the plurality of projections is separated from each of the first semiconductor element and the second semiconductor element.

14. The semiconductor device according to claim 1, wherein
the plurality of projections are disposed between each of the first semiconductor element and the second semiconductor element, and the first metal wiring, and
a plurality of recessed portions are formed in a lower surface of the first metal wiring.

15. The semiconductor device according to claim 1, wherein
the plurality of projections are disposed between each of the first semiconductor element and the second semiconductor element, and the second metal wiring, and
a plurality of recessed portions are formed in an upper surface of the second metal wiring.

16. The semiconductor device according to claim 1, wherein
the second metal wiring is bent and connected to the first metal wiring.

17. The semiconductor device according to claim 1, wherein
each of the first semiconductor element and the second semiconductor element has a round shape at a corner portion.

18. The semiconductor device according to claim 1, wherein
the second metal wiring has a protruded portion provided on an upper surface of the second metal wiring, and having a volume smaller than a volume of each of the plurality of projections.

19. The semiconductor device according to claim 1, further comprising a molding resin portion which integrally covers the substrate, the first metal wiring, the first semiconductor element, the second semiconductor element, the plurality of projections, and the second metal wiring, wherein
the molding resin portion includes a first region, and a second region having a dielectric constant different from a dielectric constant of the first region.
